(19) United States
(12) Patent Application Publication
(10) Pub. No.: US 2022/0169307 A1
(43) Pub. Date: Jun. 2, 2022

(54) INPUT POWER HEALTH DIAGNOSTIC FOR ELECTRIC POWER STEERING

(71) Applicant: STEERING SOLUTIONS IP HOLDING CORPORATION, Saginaw, MI (US)

(72) Inventors: Julie A. Kleinau, Bay City, MI (US); Steven J. Collier-Hallman, Frankenmuth, MI (US); Nicholas Gizinski, Essexville, MI (US); David M. Williams, Millington, MI (US)

(21) Appl. No.: 17/537,797

(22) Filed: Nov. 30, 2021

Related U.S. Application Data
(60) Provisional application No. 63/119,579, filed on Nov. 30, 2020.

(51) Int. Cl. B62D 5/04

(52) U.S. Cl. CPC B62D 5/0484; B62D 5/046

(57) ABSTRACT

A method for diagnosing an input power supply providing power to a motor includes: applying, using the input power supply, a power stimulus to the motor; measuring a response to the power stimulus; calculating, based on the response to the power stimulus, a metric indicative of a status of the input power supply; determining a degraded condition of the input power supply based on the metric indicative of the status of the input power supply; and performing an action in response to determining a degraded condition of the input power supply. The action may include one or more of: limiting an output power supplied to the motor; generating a diagnostic trouble code; and/or notifying an operator of the degraded condition of the input power supply.

### CROSS-REFERENCES TO RELATED APPLICATIONS

This patent application claims priority to U.S. Provisional Patent Application Ser. No. 63/119,579, filed Nov. 30, 2020, which is incorporated herein by reference in its entirety.

### TECHNICAL FIELD

This disclosure relates to electric motors and in particular to detecting a degraded condition of an input power supply to a motor, and to controlling the motor with the input power in a degraded condition.

### BACKGROUND

A vehicle, such as a car, truck, sport utility vehicle, crossover, mini-van, marine craft, aircraft, all-terrain vehicle, recreational vehicle, or other suitable vehicles, typically includes one or more electric machines, such as electric motors and the like. For example, the vehicle may include one or more motors configured to control various aspects of a steering system of the vehicle.

A high power electrical harness and connector may supply electrical power from a vehicle electrical system (e.g. battery and/or alternator) to a motor controller for one or more motors of the steering system.

Over the life of the vehicle, the high power connection properties may degrade, resulting in eventual loss of input power sufficient to deliver the desired electromechanical output power to provide the steering assist or steering angle function. This degradation is observable as an effective increase in the resistance of the power connector or harness. When attempting to deliver this electromechanical output power, the supply current draw through the increased resistance of the high power connection or harness will cause a large voltage drop between the vehicle supply and the motor controller, which may cause the total voltage at the motor controller input to be low enough to result in a “turn off” or “drop from operate state”, which may result in loss of function, such as loss of assist in an electric power steering (EPS) system, and/or loss of angle control in an advanced driver-assistance system (ADAS) or steer-by-wire (SbW) system.

### SUMMARY

This disclosure relates generally to diagnosing an input power supply providing power to a motor in a vehicle.

An aspect of the disclosed embodiments includes a method for diagnosing an input power supply providing power to a motor. The method includes: applying, using the input power supply, a power stimulus to the motor; measuring a response to the power stimulus; calculating, based on the response to the power stimulus, a metric indicative of a status of the input power supply; determining a degraded condition of the input power supply based on the metric indicative of the status of the input power supply; and performing an action in response to determining a degraded condition of the input power supply.

Another aspect of the disclosed embodiments includes a system for diagnosing an input power supply providing power to a motor in a vehicle. The system includes a processor. The memory includes instructions that, when executed by the processor, cause the processor to: apply, using the input power supply, a power stimulus to the motor; measure a response to the power stimulus; calculate, based on the response to the power stimulus, a metric indicative of a status of the input power supply; determine a degraded condition of the input power supply based on the metric indicative of the status of the input power supply; and perform an action in response to determining a degraded condition of the input power supply.

These and other aspects of the present disclosure are disclosed in the following detailed description of the embodiments, the appended claims, and the accompanying figures.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 generally illustrates an electronic power steering system according to the principles of the present disclosure.

FIG. 2 generally illustrates a controller according to the principles of the present disclosure.

FIG. 3 shows a flow diagram generally illustrating a method for controlling a motor, according to the principles of the present disclosure.

FIGS. 4A-4C show a flow diagram generally illustrating a method for controlling a motor, according to the principles of the present disclosure.

FIG. 5 shows a flow diagram generally illustrating a method for diagnosing an input power supply providing power to a motor in a vehicle, according to the principles of the present disclosure.

### DETAILED DESCRIPTION

The following discussion is directed to various embodiments of the disclosure. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

As described, a vehicle, such as a car, truck, sport utility vehicle, crossover, mini-van, marine craft, aircraft, all-terrain vehicle, recreational vehicle, or other suitable vehicles, typically includes one or more electric machines, such as electric motors and the like. For example, the vehicle may include one or more motors configured to control various aspects of a steering system of the vehicle.

A high power electrical harness and connector may supply electrical power from a vehicle electrical system (e.g. battery and/or alternator) to a motor controller for one or more motors of the steering system.

Over the life of the vehicle, the high power connection properties may degrade, resulting in eventual loss of input power sufficient to deliver the desired electromechanical output power to provide the steering assist or steering angle function. This degradation is observable as an effective increase in the resistance of the power connector or harness. When attempting to deliver this electromechanical output power, the supply current draw through the increased resistance of the high power connection or harness will cause a large voltage drop between the vehicle supply and the motor controller, which may cause the total voltage at the motor controller input to be low enough to result in a “turn off” or “drop from operate state”, which may result in loss of function, such as Loss of Assist in an electric power steering (EPS) system, and/or loss of angle control in an advanced driver-assistance system (ADAS) or steer-by-wire (SbW) system.

A vehicle system, such as an EPS system, ADAS, SbW steering system, and the like, may deliver mechanical power through use of an electromechanical actuator which includes an electric motor and a control module. Input power for the actuator is delivered through a high power electrical harness and connector which connects the vehicle electrical system (e.g. battery and/or alternator) to the EPS Control Module.

Over the life of the steering system in the vehicle the high power connection properties may degrade, resulting in eventual loss of input power sufficient to deliver the desired electromechanical output power to provide the steering assist or steering angle function. This degradation is observable as an effective increase in the resistance of the power connector or harness. When attempting to deliver this electromechanical output power the supply current draw through the increased resistance of the high power connection (or harness) will cause a large voltage drop between the vehicle supply and the EPS Control Module which may cause the total voltage at the Control Module input to be low enough to result in a “turn off” or “drop from operate state” of the steering controller resulting in loss of function (loss of assist in an EPS system, loss of angle control in an ADAS or SbW system).

In some embodiments, it is desirable to detect this degraded condition and to limit the electromechanical output power command in order to reduce the required input power and prevent loss of function of the steering system, such as loss of assist in an EPS system, or loss of angle control in an ADAS or SbW system). While performance would be reduced, this may be a preferable failure mode than full loss of the assist or angle control function.

Run time diagnostics to monitor the status of the connection health are possible. However, such run time diagnostics but may require addition of additional sensor signals (such as a battery current measurement circuit) or vehicle signals not readily available within the EPS/SbW systems (e.g. battery voltage). They also may require significant processor resources. Run time diagnostics may also require a significant non-zero motor torque in order to work properly.

In some embodiments, it is desirable to have a method to determine degradation of the input power connection (or harness) using only available signals within the existing control module and software. It is desirable to have the possibility to detect this condition in a zero motor torque condition at start up. It is desirable to have a response where the power management function of the steering system limits the output power in order to limit the input power drawn during this condition with the purpose of preventing a large enough supply voltage drop which would turn the EPS/SbW Control module off, resulting in loss of function. It is desirable to have some form of driver warning, whether through the reduced performance or a fault code and possibly fault lamp.

In some embodiments, a startup diagnostic for electric power steering input power health function of the present disclosure has the following properties: it may be run as a one-time start up diagnostic; and it may operate on a stimulus/response measurement/action philosophy.
For an EPS system: electric power is applied to the motor phases and the response is measured. The power applied is V*I (vector quantities of applied motor voltage and motor current). The electric power applied is of a nature to produce zero motor torque. The measurement of the response is the voltage at the control module input (bridge voltage). The action is the application of a output power limit and driver notification if the metric calculated from the measurement exceeds a given threshold or thresholds.
For ADAS and SbW systems: electric power is applied to the motor phases and the response(s) are measured. The electric power applied is not necessarily of a zero torque nature. If the electric power applied is intended to measure the input power health only, electric power which results in zero torque is applied and the measurement of the response is the voltage at the control module input (bridge voltage). If there is an additional desire to check for mechanical connection robustness or power electronic health at the same time then electric power which results in non-zero motor torque is applied and the measurement of the response includes motor shaft angle in addition to bridge voltage. The action if the metric(s) calculated from the measurement exceed defined threshold(s) may include an output power limit, driver notification, and if the motor moves incorrectly the action could prevent the vehicle from moving.

In some embodiments, the diagnostic utilizes the property of PMSM (Permanent Magnet Synchronous Machines—SPM) where a motor current may be commanded on the direct axis only (Id), with a zero motor current command on the quadrature axis (Iq) which does not produce motor torque and therefore should not produce handwheel motion. In some embodiments, a non-zero Iq stimulus may be used, for example, if an output torque or motion is desired. This may be especially desirable in an ADAS or SbW system. Any combination of Iq and Id deemed desirable for the system of interest is within the scope of the present disclosure.

In some embodiments, the diagnostic uses existing signals available in a steering control system, such as an EPS or SbW system.

In some embodiments, a startup diagnostic includes: application of a stimulus, detection of a response, and taking an action. The stimulus may include applying electrical power to the motor. The action may be dependent of the requirements of a given product line or system architecture. The present disclosure provides for the use of a motor to apply non-torque producing current to elicit a measurable response, which may be imperceptible by a driver). In some embodiments, the subject diagnostic works in zero-torque condition. In some embodiments, the subject diagnostic does not require battery current measurement circuit or vehicle battery voltage. In some embodiments, the subject diagnostic includes the use of a power management supply current limit interface to respond to a health metric and to limit output power, not just assist torque.

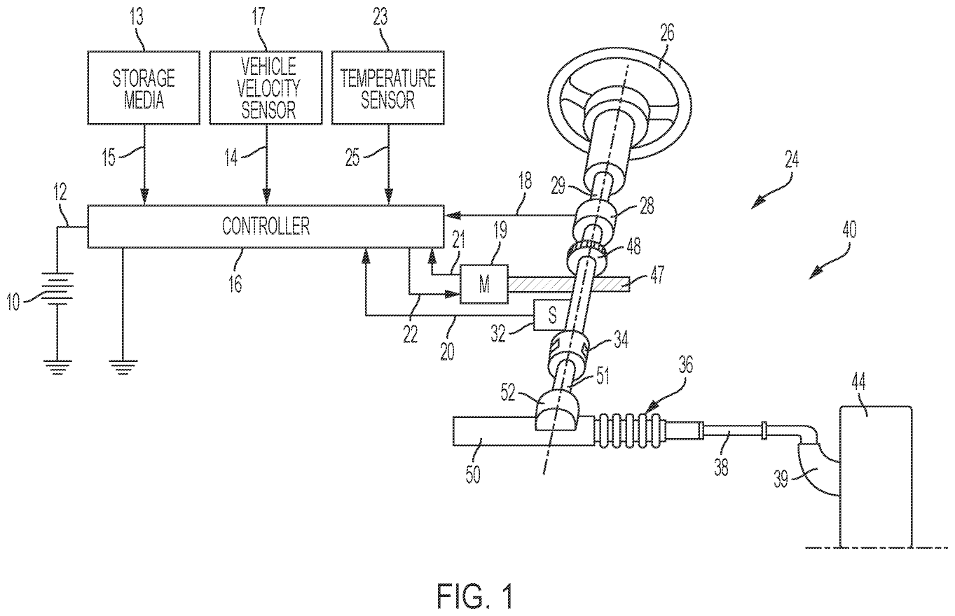

FIG. 1 generally illustrates an electric power steering system (EPS) 40 according to the principles of the present disclosure. A steering mechanism 36 includes a rack-and-pinion type system and includes a toothed rack (not shown) within housing 50 and a pinion gear (also not shown) located under gear housing 52. As the operator input, hereinafter denoted as a steering wheel 26 (e.g. a hand wheel and the like) is turned, the upper steering shaft 29 turns and the lower steering shaft 51, connected to the upper steering shaft 29 through universal joint 34, turns the pinion gear. Rotation of the pinion gear moves the rack, which moves tie rods 38 (only one shown) in turn moving the steering knuckles 39 (only one shown), which turn a steerable wheel(s) 44 (only one shown).

Steering assist is provided through the control system generally designated by reference numeral 24 and includes the controller 16 and an electric machine, which includes a permanent magnet synchronous motor, and is hereinafter denoted as motor 19. The controller 16 is powered by the vehicle power supply 10 through a wiring harness 12. The wiring harness 12 may include one or more conductors, such as lengths of wire, bus bars, etc. In some embodiments, the wiring harness 12 includes one or more connectors, such as spade connectors, receptacles, plugs, lugs, wiring terminals, etc. The controller 16 receives a vehicle speed signal 14 representative of the vehicle velocity from a vehicle velocity sensor 17. Steering angle is measured through position sensor 32, which may be an optical encoding type sensor, variable resistance type sensor, or any other suitable type of position sensor, and supplies to the controller 16 a position signal 20. Motor velocity may be measured with a tachometer, or any other device, and transmitted to controller 16 as a motor velocity signal 21. A motor velocity denoted ω_m may be measured, calculated or a combination thereof. For example, the motor velocity ω_m may be calculated as the change of the motor position θ as measured by a position sensor 32 over a prescribed time interval. For example, motor velocity ω_m may be determined as the derivative of the motor position θ from the equation ω_m=Δθ/Δt where Δt is the sampling time and Δθ is the change in position during the sampling interval. Alternatively, motor velocity may be derived from motor position as the time rate of change of position. It will be appreciated that there are numerous well-known methodologies for performing the function of a derivative.

As the steering wheel 26 is turned, torque sensor 28 senses the torque applied to the steering wheel 26 by the vehicle operator. The torque sensor 28 may include a torsion bar (not shown) and a variable resistive-type sensor (also not shown), which outputs a variable torque signal 18 to controller 16 in relation to the amount of twist on the torsion bar. Although this is one type of torque sensor, any other suitable torque-sensing device used with known signal processing techniques will suffice. In response to the various inputs, the controller 16 sends a command 22 to the motor 19, which supplies torque assist to the steering system through worm 47 and worm gear 48, providing torque assist to the vehicle steering.

It should be noted that although the disclosed embodiments are described by way of reference to motor control for electric steering applications, it will be appreciated that such references are illustrative only and the disclosed embodiments may be applied to any motor control application employing an electric motor, e.g., steering, valve control, and the like. Moreover, the references and descriptions herein may apply to many forms of parameter sensors, including, but not limited to torque, position, speed and the like. It should also be noted that reference herein to electric machines including, but not limited to, motors, hereafter, for brevity and simplicity, reference will be made to motors only without limitation.

In the control system 24 as depicted, the controller 16 utilizes the torque, position, and speed, and like, to compute a command(s) to deliver the required output power. The control system 24 may provide, for example, EPS, SbW, and/or steering control for ADAS applications. Controller 16 is disposed in communication with the various systems and sensors of the motor control system. Controller 16 receives signals from each of the system sensors, quantifies the received information, and provides an output command signal(s) in response thereto, in this instance, for example, to the motor 19. Controller 16 is configured to develop the corresponding voltage(s) by an inverter (not shown), which may optionally be incorporated with controller 16 and will be referred to herein as controller 16, such that, when applied to the motor 19, the desired torque or position is generated. In one or more examples, the controller 16 operates in a feedback control mode, as a current regulator, to generate the command 22. Alternatively, in one or more examples, the controller 16 operates in a feedforward control mode to generate the command 22. Because these voltages are related to the position and speed of the motor 19 and the desired torque, the position and/or speed of the rotor and the torque applied by an operator are determined. A position encoder is connected to the steering shaft 51 to detect the angular position θ. The encoder may sense the rotary position based on optical detection, magnetic field variations, or other methodologies. Typical position sensors include potentiometers, resolvers, synchros, encoders, and the like, as well as combinations comprising at least one of the forgoing. The position encoder outputs a position signal 20 indicating the angular position of the steering shaft 51 and thereby, that of the motor 19.

Desired torque may be determined by one or more torque sensors 28 transmitting torque signals 18 indicative of an applied torque. One or more exemplary embodiments include such a torque sensor 28 and the torque signal(s) 18 therefrom, as may be responsive to a compliant torsion bar, T-bar, spring, or similar apparatus (not shown) configured to provide a response indicative of the torque applied.

In one or more examples, a temperature sensor 23 is located at the motor 19. The temperature sensor 23 may be configured to directly measure a temperature of the sensing portion of the motor 19. The temperature sensor 23 transmits a temperature signal 25 to the controller 16 to facilitate the processing prescribed herein and compensation. Typical temperature sensors include thermocouples, thermistors, thermostats, and the like, as well as combinations comprising at least one of the foregoing sensors, which when appropriately placed provide a calibratable signal proportional to the particular temperature.

The position signal 20, velocity signal 21, and a torque signal(s) 18 among others, are applied to the controller 16. The controller 16 processes all input signals to generate values corresponding to each of the signals resulting in a rotor position value, a motor velocity value, and a torque value being available for the processing in the algorithms as prescribed herein. Measurement signals, such as the above mentioned are also commonly linearized, compensated, and filtered as desired to enhance the characteristics or eliminate undesirable characteristics of the acquired signal. For example, the signals may be linearized to improve processing speed, or to address a large dynamic range of the signal. In addition, frequency or time-based compensation and filtering may be employed to eliminate noise or avoid undesirable spectral characteristics.

In order to perform the prescribed functions and desired processing, as well as the computations therefore (e.g., the identification of motor parameters, control algorithm(s), and the like), controller 16 may include, but not be limited to, a processor(s), computer(s), DSP(s), memory, storage, register(s), timing, interrupt(s), communication interface(s), and input/output signal interfaces, and the like, as well as combinations comprising at least one of the foregoing. For example, controller 16 may include input signal processing and filtering to enable accurate sampling and conversion or acquisitions of such signals from communications interfaces.

In some embodiments, a vehicle may include a driver-assistance system (ADAS) or steer-by-wire (SbW) system, which may be similar or identical to the EPS 40, as described and as shown in FIG. 1. In some embodiments, such an ADAS or SbW system may include no steering wheel 26 or a steering wheel 26 with no physical connection to the steerable wheel(s) 44. In some embodiments, a feedback actuator (not shown) may provide a feedback torque to the steering wheel 26 to simulate feeling of torque being transmitted from the steerable wheel(s) 44. In some embodiments, an ADAS or SbW system may be operated in some modes where torque is applied by the motor 19 to the steerable wheel(s) 44, and where no corresponding feedback signal is generated or transmitted to the steering wheel 26.

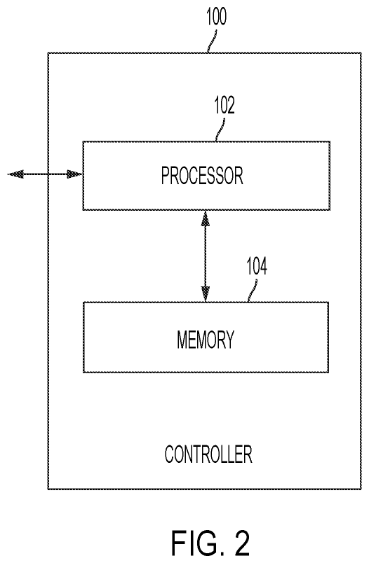

As described, the EPS 40 may be associated with a vehicle. The vehicle may include a plurality of controllers and/or electronic control units. As is generally illustrated in FIG. 2, the vehicle may include a controller 100. The controller 100 may include any suitable controller. For example, the controller 100 may include features similar to the controller 16. The controller 100 may be configured to control, for example, various aspects of the vehicle, such as aspect of the EPS 40 and/or other suitable features or components of the vehicle. The controller 100 may include a processor 102 and a memory 104. The controller 100 may apply, during a system startup, a power stimulus to the motor; measure a response to the application of the power stimulus to the motor; calculate, based on the response to the application of the power stimulus, a metric indicative of a status of an input power supply; compare the metric indicative of the status of the input power supply with a baseline metric to determine a degraded condition of the input power supply; and perform an action in response to determining a degraded condition of the input power supply.

The processor 102 may include any suitable processor, such as those described herein. Additionally, or alternatively, the controller 100 may include any suitable number of processors, in addition to or other than the processor 102. The memory 104 may comprise a single disk or a plurality of disks (e.g., hard drives), and includes a storage management module that manages one or more partitions within the memory 104. In some embodiments, memory 104 may include flash memory, semiconductor (solid state) memory or the like. The memory 104 may include Random Access Memory (RAM), a Read-Only Memory (ROM), or a combination thereof. The memory 104 may include instructions that, when executed by the processor 102, cause the processor 102 to, at least, control various functions of the vehicle.

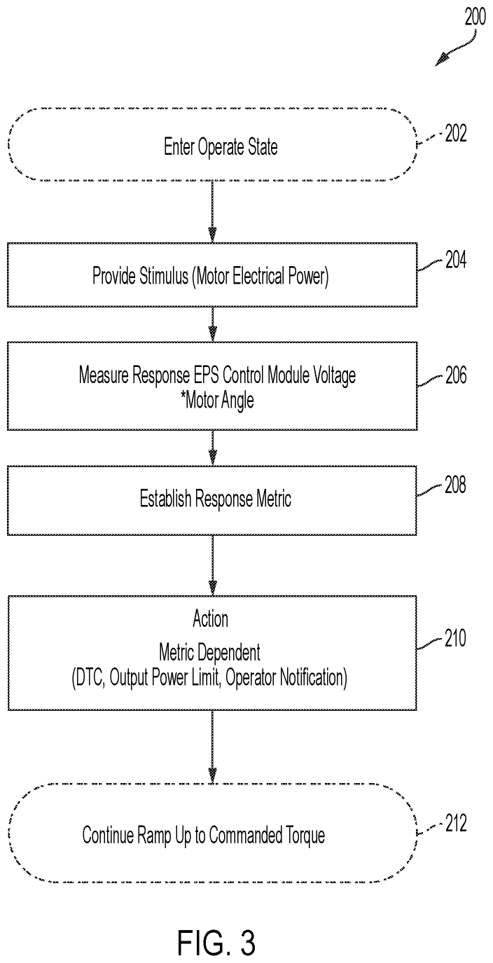

FIG. 3 is a flow diagram generally illustrating a method 200 for controlling a motor 19, according to the principles of the present disclosure. The method 200 can be performed by the controller 100, in accordance with some embodiments of the present disclosure. As can be appreciated in light of the disclosure, the order of operation within the method is not limited to the sequential execution as illustrated in FIG. 3, but may be performed in one or more varying orders as applicable and in accordance with the present disclosure.

At 202, the method 200 starts by entering an operating state. For example, the controller 100 may start performing the method 200 during a system startup, such as a vehicle startup or accessory power energization procedure. In some embodiments, the method 200 may be run as part of an initialization (init) function at the beginning of an “Operate” state of a control system 24.

At 204, the method 200 provides a stimulus in the form of electrical power to the motor 19. For example in some embodiments, the controller 100 may cause an inverter to apply V*I (vector quantities of applied motor voltage and motor current) electric power to motor phases of the motor 19, In some embodiments, for example in ADAS and SbW applications, the electric power applied to the motor 19 causes the motor 19 to produce a non-zero motor torque. In some embodiments, such as in EPS applications, the electric power applied is of a nature to cause the motor 19 to produce zero motor torque. For example, a Permanent Magnet Synchronous Machine (PMSM) type of motor 19 may be supplied with a motor current on the direct axis only (Id), with a zero motor current command on the quadrature axis (Iq) which does not produce Motor Torque, and therefore should not produce handwheel motion. In some embodiments, a torque command to the motor 19 is held to zero while the Electrical Power Excitation is applied.

At 206 the method 200 measures a response to the application of the power stimulus to the motor 19. For example, the input voltage may be measured on a power input of the controller 16 where the controller 16 receives power from the vehicle power supply 10 via the wiring harness 12, while the power stimulus is applied to the motor 19. In some embodiments, such as where the electric power applied to the motor 19 causes the motor 19 to produce a non-zero torque, the response measured at step 206 includes a motor angle of the motor 19.

At 208 the method 200 calculates, based on the response to the application of the power stimulus, a response metric. The response metric may also be called simply a “metric”. This response metric may be indicative of a status of an input power supply, such as the power supplied from the vehicle power supply 10 to the controller 16 via the wiring harness 12. For example, the controller 100 may measure a sag in the input voltage resulting from the application of electric power to the motor 19, and multiply an amount of that sag by a predetermined constant to calculate the response metric. In some embodiments, the response metric may be proportional to an estimated resistance on the power supply to the controller 16. In some embodiments, the response metric may not be proportional to an estimated resistance on the power supply to the controller 16.

At 210 the method 200 performs an action based upon the metric. For example, the controller 100 may take an action in response to determining the metric indicates a fault or other indicator of a degraded condition. Step 210 may include comparing the metric indicative of the status of the input power supply with a baseline metric to determine if the metric is indicative of a degraded condition of the input power supply, and the action may be performed only in response to determining the degraded condition of the input power supply. The action or response to be performed may depend on a value or values of the metric. Actions to be taken may include, for example, generating a diagnostic trouble code (DTC), limiting output power of the motor 19, and/or notifying an operator of the vehicle. Generating the DTC may include storing the DTC in memory of one or more electronic control units, such as a powertrain control module (PCM) or an EPS controller. Other associated data may be stored with the DTC, such as date and time of generation, and associated parameters and/or conditions. Notifying the operator of the vehicle may include setting a dashboard warning light and/or a HMI message indicating that service is required.

At 212 the method 200 concludes by ramping-up the motor 19 to a commanded torque. For example, step 212 may include the control system 24 resuming functional operation. Such functional operation may be impacted by the action, for example, in cases where output power of the motor 19 is limited.

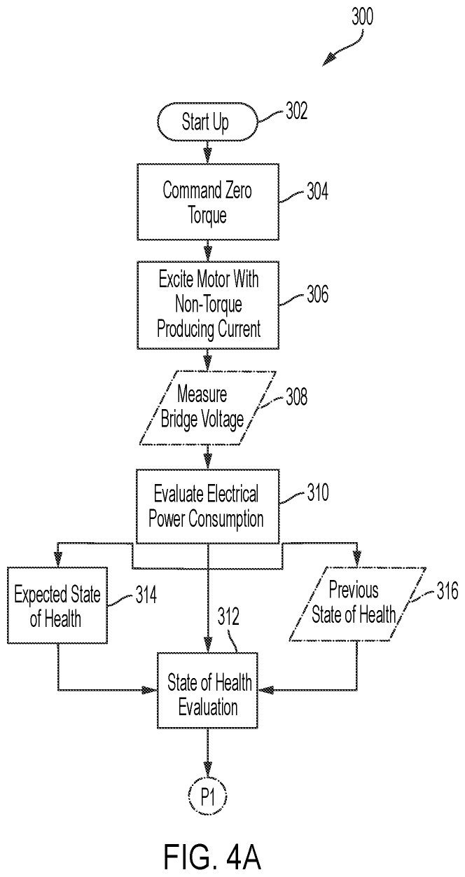

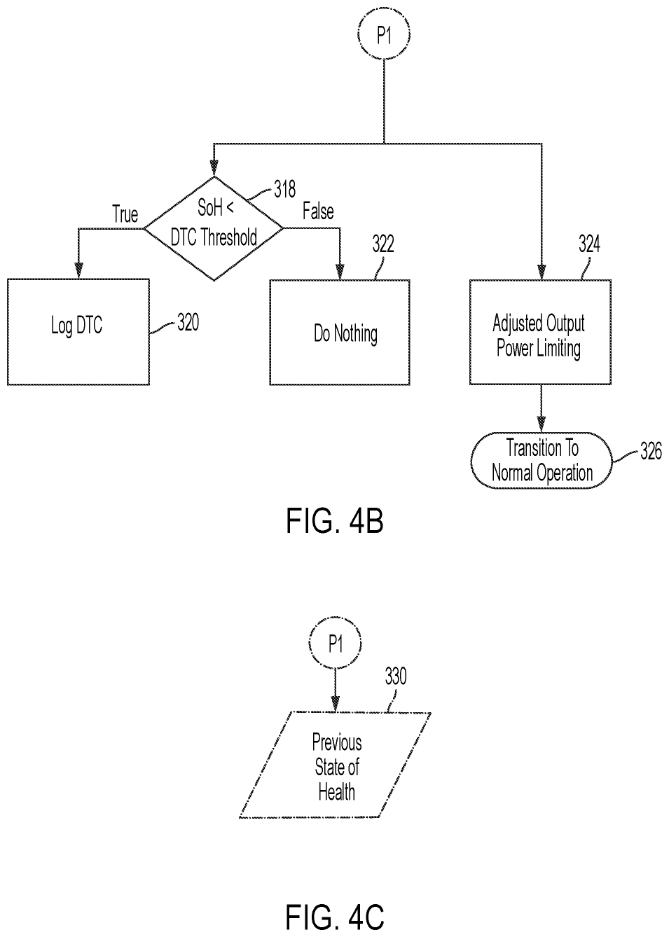

FIGS . 4A-4C show a flow diagram generally illustrating a method 300 for controlling a motor 19, according to the principles of the present disclosure. The method 300 can be a variation and/or a specific version of the method 200 shown in FIG. 3. The method 300 can be performed by the controller 100, in accordance with some embodiments of the present disclosure. As can be appreciated in light of the disclosure, the order of operation within the method is not limited to the sequential execution as illustrated in FIGS. 4A-4C, but may be performed in one or more varying orders as applicable and in accordance with the present disclosure.

At 302, the method 300 starts with a startup event. For example, the controller 100 may start performing the method 300 during a system startup, such as a vehicle startup or accessory power energization procedure. In some embodiments, the method 300 may be run as part of an initialization (init) function at the beginning of an “Operate” state of a control system 24.

At 304, the method 300 commands the motor 19 to produce zero torque. For example, the controller 100 may cause the motor 19 to be in a non-torque producing mode for some period of time during the method 300. The motor 19 may include a motor in an EPS system and/or a SbW system.

At 306, the method 300 excites the motor 19 with a non-torque producing current. For example in some embodiments, the controller 100 may cause an inverter to apply V*I (vector quantities of applied motor voltage and motor current) electric power to motor phases of the motor 19.

At 308, the method 300 measures a bridge voltage. The bridge voltage may be a voltage between conductors of the wiring harness 12 that supplies power from the vehicle power supply 10 to the controller 16. For example, the bridge voltage may be a voltage of a power supply input from the wiring harness 12 at the controller 16, and which is rectified and converted or otherwise controlled by the controller 16 to power the motor 19. Alternatively or additionally, the bridge voltage may include a voltage across a DC bridge within the controller 16 and which is input to an inverter providing AC power to the motor 19.

At 310, the method 300 evaluates an electrical power consumption. For example, the controller 100 may compute an amount of power consumed by the motor 19 and the controller 16, based on the bridge voltage and the applied motor voltage and motor current supplied to the motor 19. Additionally the controller 100 may compute the power consumed by the wiring harness 12, and knowing the voltage may calculate a resistance of the wiring harness 12. By inducing a current load through the motor 19 and causing a current draw on the wiring harness 12 and looking the voltage bridge effect, the system and method of the present disclosure may evaluate the power consumption on one or both of the wiring harness 12 that supplies the controller 16 and/or on a motor wiring connection (not shown) which electrically connects the controller 16 and the motor 19. By evaluating the power consumption on the wiring harness 12 and/or the motor wiring connection, the controller 16 may effectively evaluate a resistance of the wiring harness 12 and/or the motor wiring connection. The motor wiring connection may include one or more conductors, such as wires or bus bars, and/or one or more connectors, such as spade connectors, receptacles, plugs, lugs, wiring terminals, etc., etc.

At 312, the method 300 performs a state of health (SoH) evaluation. For example, the controller 100 may compute a preliminary SoH value based on the electrical power consumption, harness resistance, and/or the bridge voltage. Alternatively or additionally, the controller 100 may determine a new SoH value based on the preliminary SoH value in combination with one or more other factors, such as an expected SoH and/or one or more pervious SoH values.

At 314, the method 300 determines the expected SoH. The expected SoH may also be called a baseline SoH. For example, the controller 100 may compute the expected SoH value based on the electrical power consumption, when the power supply is in a healthy or non-degraded condition. Step 312 may use the expected SoH for computing a new SoH value. For example, one factor in determining the new SoH may be a difference between the preliminary SoH value and one or more expected SoH values.

At 316, the method 300 determines a previous SoH value. For example, the controller 100 may load one or more pervious SoH values from a storage memory. Step 312 may use the previous SoH value for computing a new SoH value. For example, one factor in determining the new SoH may be a degree of change from one or more previous SoH values.

In some embodiments, the controller 100 includes logic to track the previous state of the metric (e.g. one or more previous SoH values) in order to facilitate decisions on whether to latch the reduced output power behavior or reset performance back to full. It may also be used for other purposes, such as learning expected behavior of the specific system at startup and adjusting metric calculations.

FIG. 4B shows a continuation of the method 300, in accordance with some embodiments. At step 318, the method 300 determines if an DTC threshold is met. For example, the controller 100 may compare the SoH value computed at step 312 to a predetermined DTC threshold value.

At step 320, the method 300 logs an DTC in response to determining that the DTC threshold is met at step 318. For example, the controller 100 may log the DTC, which may include storing a time and/or other parameters when the DTC threshold was met.

At step 322, the method 300 does nothing in response to determining that the DTC threshold is not met at step 318. For example, the controller 100 proceed with other tasks in response to determining that the DTC threshold is not met.

At step 324, the method 300 adjusts an output power limiting. For example, the controller 100 may adjust an output power limiting value that controls a maximum limit of power that is output to the motor 19 in response to the SoH value. In some embodiments, a SoH value that is indicative of the input power supply having a degraded condition may cause the output power limiting value to be set to a predetermined value or to be increased by a predetermined amount.

At step 326, the method 300 transitions to normal operation. For example, the controller 100 may operate the system with the motor 19 in an operational mode for producing torque to steer the vehicle. The normal operation may continue with the output power to the motor 19 limited by the output power limiting value.

In some embodiments, and as shown in FIG. 4C, the method 300 includes storing a previous SoH value. For example, the controller 100 may store the SoH value calculated at step 312 into a storage memory for future reference, and/or for future use, such as in step 316.

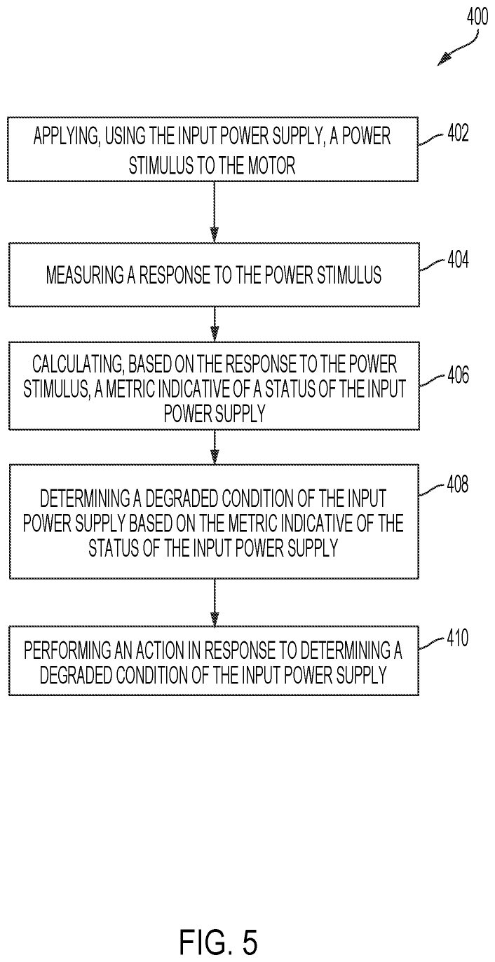

FIG. 5 shows a flow diagram generally illustrating a method 400 for diagnosing an input power supply providing power to a motor in a vehicle, according to the principles of the present disclosure. The method 400 can be performed by the controller 100, in accordance with some embodiments of the present disclosure. As can be appreciated in light of the disclosure, the order of operation within the method is not limited to the sequential execution as illustrated in FIG. 5, but may be performed in one or more varying orders as applicable and in accordance with the present disclosure.

At step 402, the method 400 applies, using the input power supply, a power stimulus to the motor. For example in some embodiments, the controller 100 may cause an inverter to apply V*I (vector quantities of applied motor voltage and motor current) electric power to motor phases of the motor 19. The motor 19 may include a motor in an EPS system and/or a SbW system.

At step 404, the method 400 measures a response to the power stimulus. For example, the input voltage may be measured on a power input of the controller 16 where the controller 16 receives power from the vehicle power supply 10 via the wiring harness 12, while the power stimulus is applied to the motor 19. Alternatively or additionally, the input voltage may include a bridge voltage of a DC bridge which supplies DC power to an inverter providing AC power to the motor 19. In some embodiments, such as where the electric power applied to the motor 19 causes the motor 19 to produce a non-zero torque, the response measured at step 206 includes a motor angle of the motor 19. For example, the non-zero torque produced by the motor 19 should cause a corresponding change in the motor angle of the motor 19. A motor angle measurement that does not change in an expected manor in response to applying the torque-producing electric power to the motor 19 may indicate a problem with the motor 19 or some other component of the system.

At step 406, the method 400 calculates, based on the response to the power stimulus, a metric indicative of a status of the input power supply. The status of the input power supply, may include the status of the power supplied from the vehicle power supply 10 to the controller 16 via the wiring harness 12. For example, the controller 100 may measure a sag in the input voltage resulting from the application of electric power to the motor 19, and multiply an amount of that sag by a predetermined constant to calculate the response metric. In some embodiments, the response metric may be proportional to an estimated resistance on the power supply to the controller 16. The estimated resistance may include a resistance in the wiring harness 12. In some embodiments, the response metric may not be proportional to an estimated resistance on the power supply to the controller 16.

At step 408, the method 400 determines a degraded condition of the input power supply based on the metric indicative of the status of the input power supply. For example, the controller 100 may compare the metric indicative of the status of the input power supply with a baseline value to determine if the metric is indicative of a degraded condition of the input power supply.

At step 410, the method 400 performs an action in response to determining a degraded condition of the input power supply. For example, the controller 100 may take an action in response to determining the degraded condition of the input power supply. The action may depend on a value or values of the metric. The action may include, for example, generating a diagnostic trouble code (DTC), limiting output power of the motor 19, and/or notifying an operator of the vehicle. Generating the DTC may include storing the DTC in memory of one or more electronic control units, such as a powertrain control module (PCM) or an EPS controller.

A method for diagnosing an input power supply providing power to a motor is provided. The method includes: applying, using the input power supply, a power stimulus to the motor; measuring a response to the power stimulus; calculating, based on the response to the power stimulus, a metric indicative of a status of the input power supply; determining a degraded condition of the input power supply based on the metric indicative of the status of the input power supply; and performing an action in response to determining a degraded condition of the input power supply.

In some embodiments, applying the power stimulus to the motor and measuring the response to the power stimulus are performed during at least one of a system startup or a shutdown of a vehicle.

In some embodiments, applying the power stimulus to the motor causes the motor to produce zero output torque.

In some embodiments, measuring the response to the power stimulus to the motor includes measuring an input voltage of the input power supply.

In some embodiments, applying the power stimulus to the motor causes the motor to produce a non-zero output torque; and measuring the response to the power stimulus to the motor includes measuring a motor angle of the motor.

In some embodiments, performing the action in response to determining the degraded condition of the input power supply includes limiting an output power supplied to the motor.

In some embodiments, performing the action in response to determining the degraded condition of the input power supply includes at least one of generating a diagnostic trouble code and notifying an operator of the degraded condition of the input power supply.

In some embodiments, determining the degraded condition of the input power supply based on the metric indicative of the status of the input power supply further includes: storing a value of the metric indicative of the status of the input power supply; determining a baseline metric based on one or more previously stored values of the metric indicative of the status of the input power supply; and comparing the metric indicative of the status of the input power supply with the baseline metric to determine the degraded condition of the input power supply.

In some embodiments, determining the degraded condition of the input power supply based on the metric indicative of the status of the input power supply further includes: storing a value of the metric indicative of the status of the input power supply; and comparing one or more previously stored values of the metric indicative of the status of the input power supply with a baseline metric to determine the degraded condition of the input power supply.

In some embodiments, the motor is associated with a steering system of a vehicle.

A system for diagnosing an input power supply providing power to a motor in a vehicle is provided. The system includes: a processor; and a memory including instructions that, when executed by the processor, cause the processor to: apply, using the input power supply, a power stimulus to the motor; measure a response to the power stimulus; calculate, based on the response to the power stimulus, a metric indicative of a status of the input power supply; determine a degraded condition of the input power supply based on the metric indicative of the status of the input power supply; and perform an action in response to determining a degraded condition of the input power supply.

In some embodiments, applying the power stimulus to the motor and measuring the response to the power stimulus are performed during at least one of a system startup or a shutdown of the vehicle.

In some embodiments, applying the power stimulus to the motor causes the motor to produce zero output torque.

In some embodiments, measuring the response to the power stimulus to the motor includes measuring a motor angle of the motor.

In some embodiments, measuring the response to the power stimulus to the motor includes the instructions causing the processor to measure an input voltage from the input power supply.

In some embodiments, the action in response to determining the degraded condition of the input power supply includes the instructions causing the processor to limit an output power supplied to the motor.

In some embodiments, the action in response to determining the degraded condition of the input power supply includes the instructions causing the processor to perform least one of: generating a diagnostic trouble code and notifying an operator of the degraded condition of the input power supply.

In some embodiments, determining the degraded condition of the input power supply based on the metric indicative of the status of the input power supply further comprises the instructions causing the processor to: store a value of the metric indicative of the status of the input power supply; determine a baseline metric based on one or more previously stored values of the metric indicative of the status of the input power supply; and compare the metric indicative of the status of the input power supply with the baseline metric to determine the degraded condition of the input power supply.

In some embodiments, determining the degraded condition of the input power supply based on the metric indicative of the status of the input power supply further comprises the instructions causing the processor to: store a value of the metric indicative of the status of the input power supply; and compare one or more previously stored values of the metric indicative of the status of the input power supply with a baseline metric to determine the degraded condition of the input power supply.

In some embodiments, the motor is associated with a steering system of the vehicle.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

The word “example” is used herein to mean serving as an example, instance, or illustration. Any aspect or design described herein as “example” is not necessarily to be construed as preferred or advantageous over other aspects or designs. Rather, use of the word “example” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an implementation” or “one implementation” throughout is not intended to mean the same embodiment or implementation unless described as such.

Implementations the systems, algorithms, methods, instructions, etc., described herein can be realized in hardware, software, or any combination thereof. The hardware can include, for example, computers, intellectual property (IP) cores, application-specific integrated circuits (ASICs), programmable logic arrays, optical processors, programmable logic controllers, microcode, microcontrollers, servers, microprocessors, digital signal processors, or any other suitable circuit. In the claims, the term “processor” should be understood as encompassing any of the foregoing hardware, either singly or in combination. The terms “signal” and “data” are used interchangeably.

As used herein, the term module can include a packaged functional hardware unit designed for use with other components, a set of instructions executable by a controller (e.g., a processor executing software or firmware), processing circuitry configured to perform a particular function, and a self-contained hardware or software component that interfaces with a larger system. For example, a module can include an application specific integrated circuit (ASIC), a Field Programmable Gate Array (FPGA), a circuit, digital logic circuit, an analog circuit, a combination of discrete circuits, gates, and other types of hardware or combination thereof. In other embodiments, a module can include memory that stores instructions executable by a controller to implement a feature of the module.

Further, in one aspect, for example, systems described herein can be implemented using a general-purpose computer or general-purpose processor with a computer program that, when executed, carries out any of the respective methods, algorithms, and/or instructions described herein. In addition, or alternatively, for example, a special purpose computer/processor can be utilized which can contain other hardware for carrying out any of the methods, algorithms, or instructions described herein.

Further, all or a portion of implementations of the present disclosure can take the form of a computer program product accessible from, for example, a computer-usable or computer-readable medium. A computer-usable or computer-readable medium can be any device that can, for example, tangibly contain, store, communicate, or transport the program for use by or in connection with any processor. The medium can be, for example, an electronic, magnetic, optical, electromagnetic, or a semiconductor device. Other suitable mediums are also available.

The above-described embodiments, implementations, and aspects have been described in order to allow easy understanding of the present disclosure and do not limit the present disclosure. On the contrary, the disclosure is intended to cover various modifications and equivalent arrangements included within the scope of the appended claims, which scope is to be accorded the broadest interpretation to encompass all such modifications and equivalent structure as is permitted under the law.

Having thus described the invention, it is claimed:

1. A method for diagnosing an input power supply providing power to a motor, the method comprising:
applying, using the input power supply, a power stimulus to the motor;
measuring a response to the power stimulus;
calculating, based on the response to the power stimulus, a metric indicative of a status of the input power supply;
determining a degraded condition of the input power supply based on the metric indicative of the status of the input power supply; and
performing an action in response to determining a degraded condition of the input power supply.

2. The method of claim 1, wherein applying the power stimulus to the motor and measuring the response to the power stimulus are performed during at least one of a system startup or a shutdown of a vehicle.

3. The method of claim 1, wherein applying the power stimulus to the motor causes the motor to produce zero output torque.

4. The method of claim 1, wherein measuring the response to the power stimulus to the motor includes measuring an input voltage of the input power supply.

5. The method of claim 1, wherein applying the power stimulus to the motor causes the motor to produce a non-zero output torque; and
wherein measuring the response to the power stimulus to the motor includes measuring a motor angle of the motor.

6. The method of claim 1, wherein performing the action in response to determining the degraded condition of the input power supply includes limiting an output power supplied to the motor.

7. The method of claim 1, wherein performing the action in response to determining the degraded condition of the input power supply includes at least one of generating a diagnostic trouble code and notifying an operator of the degraded condition of the input power supply.

8. The method of claim 1, wherein determining the degraded condition of the input power supply based on the metric indicative of the status of the input power supply further comprises:
storing a value of the metric indicative of the status of the input power supply;
determining a baseline metric based on one or more previously stored values of the metric indicative of the status of the input power supply; and
comparing the metric indicative of the status of the input power supply with the baseline metric to determine the degraded condition of the input power supply.

9. The method of claim 1, wherein determining the degraded condition of the input power supply based on the metric indicative of the status of the input power supply further comprises:
storing a value of the metric indicative of the status of the input power supply; and
comparing one or more previously stored values of the metric indicative of the status of the input power supply with a baseline metric to determine the degraded condition of the input power supply.

10. The method of claim 1, wherein the motor is associated with a steering system of a vehicle.

11. A system for diagnosing an input power supply providing power to a motor in a vehicle, the system comprising:
a processor; and
a memory including instructions that, when executed by the processor, cause the processor to:
apply, using the input power supply, a power stimulus to the motor;
measure a response to the power stimulus;
calculate, based on the response to the power stimulus, a metric indicative of a status of the input power supply;
determine a degraded condition of the input power supply based on the metric indicative of the status of the input power supply; and
perform an action in response to determining a degraded condition of the input power supply.

12. The system of claim 11, wherein applying the power stimulus to the motor and measuring the response to the power stimulus are performed during at least one of a system startup or a shutdown of the vehicle.

13. The system of claim 11, wherein applying the power stimulus to the motor causes the motor to produce zero output torque.

14. The system of claim 13, wherein measuring the response to the power stimulus to the motor includes measuring a motor angle of the motor.

15. The system of claim 11, wherein measuring the response to the power stimulus to the motor includes the instructions causing the processor to measure an input voltage from the input power supply.

16. The system of claim 11, wherein the action in response to determining the degraded condition of the input power supply includes the instructions causing the processor to limit an output power supplied to the motor.

17. The system of claim 11, wherein the action in response to determining the degraded condition of the input power supply includes the instructions causing the processor to perform least one of: generating a diagnostic trouble code and notifying an operator of the degraded condition of the input power supply.

18. The system of claim 11, wherein determining the degraded condition of the input power supply based on the metric indicative of the status of the input power supply further comprises the instructions causing the processor to:
store a value of the metric indicative of the status of the input power supply;
determine a baseline metric based on one or more previously stored values of the metric indicative of the status of the input power supply; and
compare the metric indicative of the status of the input power supply with the baseline metric to determine the degraded condition of the input power supply.

19. The system of claim 11, wherein determining the degraded condition of the input power supply based on the metric indicative of the status of the input power supply further comprises the instructions causing the processor to:
store a value of the metric indicative of the status of the input power supply; and
compare one or more previously stored values of the metric indicative of the status of the input power supply with a baseline metric to determine the degraded condition of the input power supply.

20. The system of claim 11, wherein the motor is associated with a steering system of the vehicle.
